(19) United States
(12) Patent Application Publication
(10) Pub. No.: US 2026/0011674 A1
(43) Pub. Date: Jan. 8, 2026

(54) PACKAGE COMPRISING INTEGRATED DEVICE AND A METALLIZATION PORTION

(71) Applicant: QUALCOMM Incorporated, San Diego, CA (US)

(72) Inventors: William STONE, San Diego, CA (US); Yanmei SONG, San Diego, CA (US); Jianwen XU, San Diego, CA (US)

(21) Appl. No.: 18/766,490

(22) Filed: Jul. 8, 2024

(51) Int. Cl. H01L 23/00; H01L 23/31; H01L 23/36; H01L 25/00; H01L 25/065; H10B 80/00

(52) U.S. Cl. CPC H01L 24/24; H01L 23/3107; H01L 24/95; H01L 25/0655; H01L 23/3171; H01L 23/36; H01L 24/32; H01L 24/73; H01L 24/82; H01L 25/50; H01L 2224/24105; H01L 2224/24137; H01L 2224/24225; H01L 2224/244; H01L 2224/32221; H01L 2224/73267; H01L 2224/82005; H01L 2224/95001; H10B 80/00

(57) ABSTRACT

A package comprising a metallization portion; an integrated device comprising a plurality of pillar interconnects, wherein the integrated device is coupled to the metallization portion through the plurality of pillar interconnects; and an encapsulation layer at least partially encapsulating the integrated device, wherein the encapsulation layer is coupled to the metallization portion.

### FIELD

Various features relate to packages with integrated devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with integrated devices.

One example provides a package comprising a metallization portion; an integrated device comprising a plurality of pillar interconnects, wherein the integrated device is coupled to the metallization portion through the plurality of pillar interconnects; and an encapsulation layer at least partially encapsulating the integrated device, wherein the encapsulation layer is coupled to the metallization portion.

Another example provides a package comprising a metallization portion; an integrated device coupled to the metallization portion through the plurality of solder interconnects; and an encapsulation layer at least partially encapsulating the integrated device, wherein the encapsulation layer is coupled to the metallization portion.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a metallization portion and an integrated device with pillar interconnects.

FIG. 2 illustrates an exemplary cross sectional profile view of a package that includes a metallization portion and an integrated device with pillar interconnects.

FIG. 3 illustrates an exemplary cross sectional profile view of a package that includes a metallization portion and an integrated device with pillar interconnects.

FIG. 4 illustrates an exemplary cross sectional profile view of a package that includes a metallization portion, a first integrated device with pillar interconnects, and a second integrated device.

FIG. 5 illustrates an exemplary cross sectional profile view of a package that includes a metallization portion and an integrated device.

FIG. 6 illustrates an exemplary cross sectional profile view of a package that includes a metallization portion, a first integrated device with pillar interconnects, and a second integrated device.

FIG. 7 illustrates an exemplary cross sectional profile view of a package that includes a metallization portion, a first integrated device with pillar interconnects, a second integrated device, and a dummy die structure.

FIG. 8 illustrates an exemplary cross sectional profile view of a package that includes a metallization portion, a first integrated device with pillar interconnects, a second integrated device, and a dummy die structure.

FIG. 9 illustrates exemplary packages with different configurations of integrated devices.

FIG. 10 illustrates exemplary packages with different configurations of integrated devices.

FIGS. 11A-11C illustrate an exemplary sequence for fabricating a package that includes a metallization portion and an integrated device.

FIGS. 12A-12C illustrate an exemplary sequence for fabricating a package that includes a metallization portion and an integrated device.

FIG. 13 illustrates an exemplary flow chart of a method for fabricating a package that includes a metallization portion and an integrated device.

FIGS. 14A-14B illustrate an exemplary sequence for fabricating a metallization portion.

FIG. 15 illustrates an exemplary flow chart of a method for fabricating a metallization portion.

FIG. 16 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a metallization portion; an integrated device comprising a plurality of pillar interconnects, wherein the integrated device is coupled to the metallization portion through the plurality of pillar interconnects; and an encapsulation layer at least partially encapsulating the integrated device, wherein the encapsulation layer is coupled to the metallization portion. The configuration of the package may provide a package with high reliability, high performance, low power consumption and/or reduced latency.

### Exemplary Package Comprising an Integrated Device and a Metallization Portion

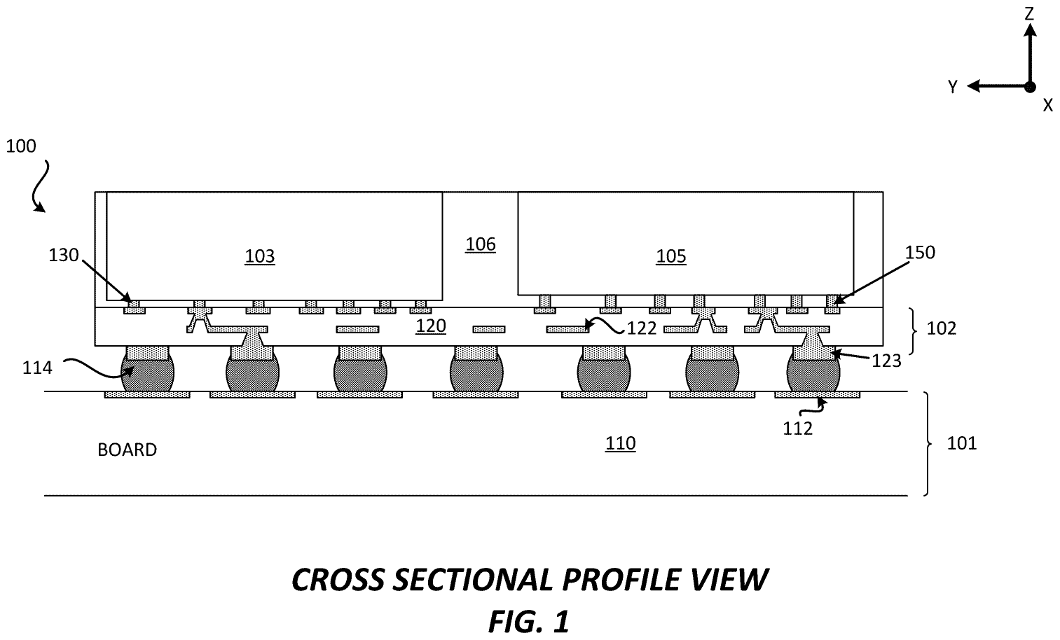

FIG. 1 illustrates a cross sectional profile view of a package 100 that includes integrated devices and a metallization portion. The package 100 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101. The package 100 may be a package with high reliability, high performance, low power consumption and/or reduced latency.

The package 100 includes a metallization portion 102, an integrated device 103, an integrated device 105 and an encapsulation layer 106. The metallization portion 102 includes at least one dielectric layer 120, a plurality of metallization interconnects 122 and a plurality of post interconnects 123. The plurality of post interconnects 123 may be coupled to the plurality of metallization interconnects 122. The plurality of post interconnects 123 may be considered part of the plurality of metallization interconnects 122. The plurality of post interconnects 123 may include a plurality of copper post interconnects. The plurality of solder interconnects 114 may be coupled to the plurality of post interconnects 123 and the plurality of board interconnects 112. The plurality of solder interconnects 114 may be coupled to the plurality of metallization interconnects 122.

The integrated device 103 may be a first integrated device. The integrated device 103 is coupled to the metallization portion 102. For example, the integrated device 103 may be coupled to the metallization portion 102 through a plurality of pillar interconnects 130. The plurality of pillar interconnects 130 may be coupled to and touch the plurality of metallization interconnects 122 of the metallization portion 102. The plurality of pillar interconnects 130 may be coupled to and touch a plurality of pad interconnects of the integrated device 103. The plurality of pillar interconnects 130 may be considered to be part of the integrated device 103.

The integrated device 105 may be a second integrated device. The integrated device 105 is coupled to the metallization portion 102. For example, the integrated device 105 may be coupled to the metallization portion 102 through a plurality of pillar interconnects 150. The plurality of pillar interconnects 150 may be coupled to and touch the plurality of metallization interconnects 122 of the metallization portion 102. The plurality of pillar interconnects 150 may be coupled to and touch a plurality of pad interconnects of the integrated device 105. The plurality of pillar interconnects 150 may be considered to be part of the integrated device 105.

The encapsulation layer 106 may be coupled to the metallization portion 102. The encapsulation layer 106 may at least partially encapsulate the integrated device 103, the integrated device 105, the plurality of pillar interconnects 130 and/or the plurality of pillar interconnects 150. The encapsulation layer 106 may include a mold, a resin, an epoxy and/or a filler.

In some implementations, the integrated device 103 may be a system on chip, and the integrated device 105 may be a memory device. In some implementations, the integrated device 103 may be a first system on chip (SoC), and the integrated device 105 may be a second system on chip (SoC).

The metallization portion 102 may include a redistribution portion. The plurality of metallization interconnects 122 may include a plurality of redistribution interconnects. A redistribution interconnect may include portions that have a U-shape or V-shape. The terms “U-shape” and” V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

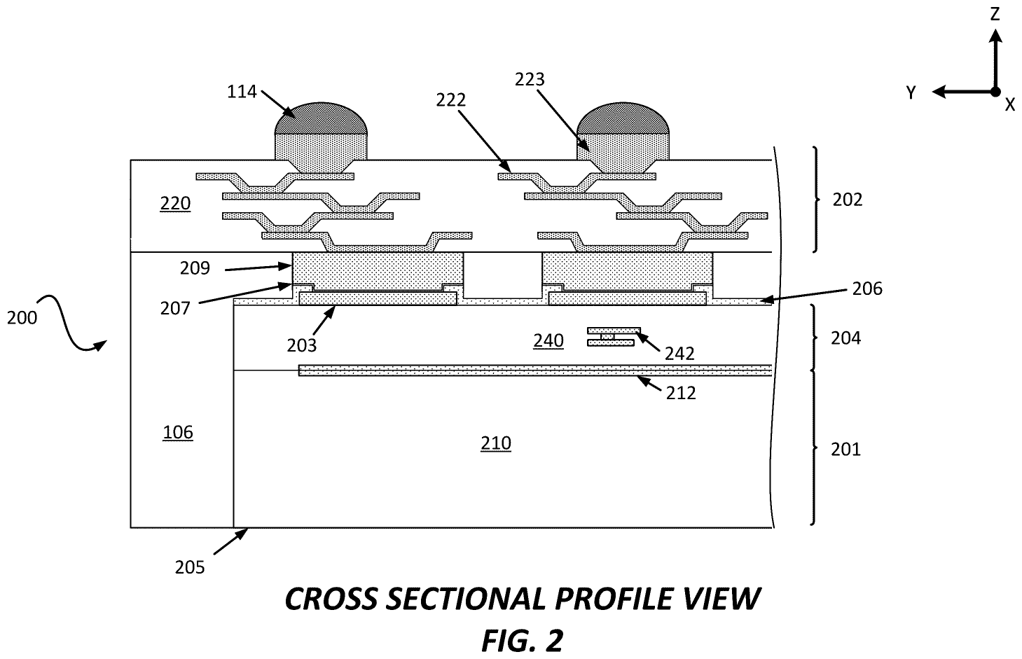

FIG. 2 illustrates a package 200 that includes an integrated device and a metallization portion. In some implementations, the package 200 may be a more detailed representation of a portion of the package 100 of FIG. 1.

The package 200 includes an integrated device 205, a metallization portion 202 and an encapsulation layer 106. The metallization portion 202 includes at least one dielectric layer 220, a plurality of metallization interconnects 222 and a plurality of post interconnects 223. The plurality of post interconnects 223 may be coupled to the plurality of metallization interconnects 222. The plurality of post interconnects 223 may be considered part of the plurality of metallization interconnects 222. A plurality of solder interconnects 114 may be coupled to the plurality of post interconnects 223. The plurality of solder interconnects 114 may be coupled to the plurality of metallization interconnects 222. The encapsulation layer 106 may be coupled to the metallization portion 202. The metallization portion 202 may represent the metallization portion 102.

The integrated device 205 may represent any of the integrated devices described in the disclosure. For example, the integrated device 205 (or a variation) may represent the integrated device 103 and/or the integrated device 105.

The integrated device 205 includes a die substrate portion 201 and a die interconnection portion 204. The die substrate portion 201 includes a die substrate 210, an active region 212. The active region 212 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 212 of the die substrate 210.

The die substrate 210 may include silicon (Si). The die substrate 210 may comprise a bulk silicon. The bulk silicon may include a monolith silicon. Different implementations may have different thicknesses for the die substrate 210.

The die interconnection portion 204 includes at least one dielectric layer 240 and a plurality of die interconnects 242. The die interconnection portion 204 is coupled to the die substrate portion 201. The plurality of die interconnects 242 are coupled to the active region 212 of the die substrate portion 201. The die interconnection portion 204 may also include a plurality of pad interconnects 203 and a passivation layer 206. In some implementations, a back end of line (BEOL) process may be used to fabricate the die interconnection portion 204. The integrated device 205 may include a front side and a back side. The front side of the integrated device 205 may be a side that includes the plurality of pad interconnects 203. The plurality of pad interconnects 203 may be coupled to the plurality of die interconnects 242. The back side of the integrated device 205 may be a side that includes the die substrate 210. A plurality of under bump metallization interconnects 207 is coupled to the plurality of pad interconnects 203. The plurality of under bump metallization interconnects 207 may include a seed layer. A plurality of pillar interconnects 209 may be coupled to the plurality of bump metallization interconnects 207 and/or the plurality of pad interconnects 203. A plurality of pillar interconnects 209 may touch the plurality of bump metallization interconnects 207 and/or the plurality of pad interconnects 203. In some implementations, the plurality of under bump metallization interconnects 207 may be considered part of the plurality of pillar interconnects 209. In some implementations, the plurality of pillar interconnects 209 and/or the plurality of under bump metallization interconnects 207 may be considered part of the integrated device 205.

The integrated device 205 is coupled to the metallization portion 202. For example, the integrated device 205 is coupled to the metallization portion 202 through the plurality of pillar interconnects 209. The plurality of pillar interconnects 209 may be coupled to and touch the plurality of metallization interconnects 222 of the metallization portion 202.

In some implementations, an electrical path to and/or from an active region 212 may include at least one die interconnect from the plurality of die interconnects 242, at least one pad interconnect from the plurality of pad interconnects 203, at least one under bump metallization interconnect from the plurality of under bump metallization interconnects 207, at least one pillar interconnect from the plurality of pillar interconnects 209, at least one metallization interconnect from the plurality of metallization interconnects 222, at least one post interconnect from the plurality of post interconnects 223 and/or at least one solder interconnect from the plurality of solder interconnects 114.

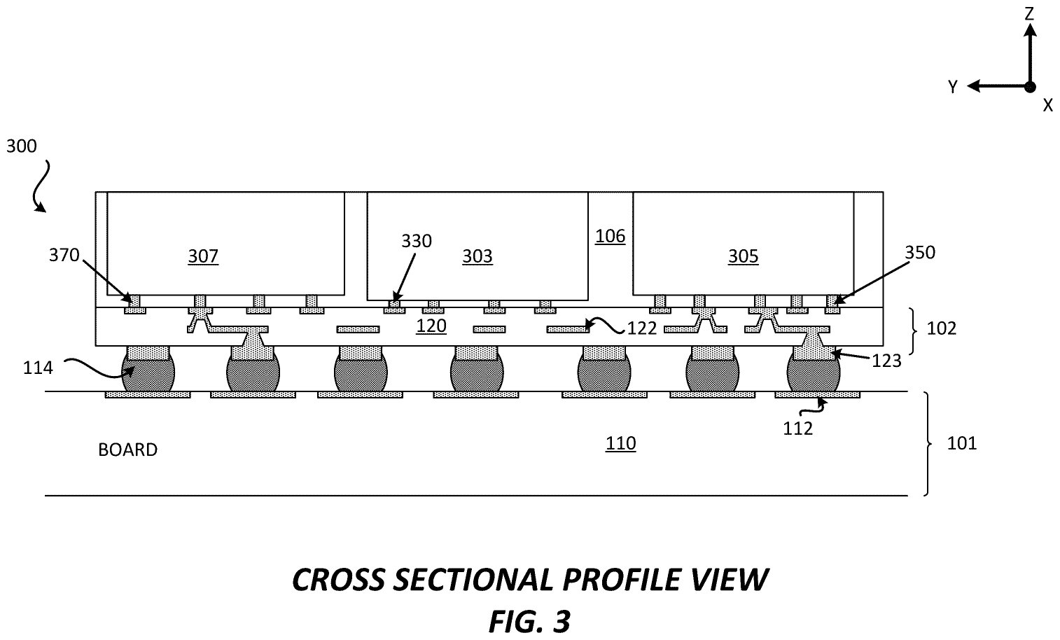

FIG. 3 illustrates a cross sectional profile view of a package 300 that includes integrated devices and a metallization portion. The package 300 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 300 includes a metallization portion 102, an integrated device 303, an integrated device 305, an integrated device 307 and an encapsulation layer 106. The metallization portion 102 includes at least one dielectric layer 120, a plurality of metallization interconnects 122 and a plurality of post interconnects 123. The plurality of post interconnects 123 may be coupled to the plurality of metallization interconnects 122. The plurality of post interconnects 123 may be considered part of the plurality of metallization interconnects 122. The plurality of solder interconnects 114 may be coupled to the plurality of post interconnects 123 and the plurality of board interconnects 112. The plurality of solder interconnects 114 may be coupled to the plurality of metallization interconnects 122.

The integrated device 303 may be a first integrated device. The integrated device 303 is coupled to the metallization portion 102. For example, the integrated device 303 may be coupled to the metallization portion 102 through a plurality of pillar interconnects 330. The plurality of pillar interconnects 330 may be coupled to and touch the plurality of metallization interconnects 122 of the metallization portion 102. The plurality of pillar interconnects 330 may be coupled to and touch a plurality of pad interconnects of the integrated device 303. The plurality of pillar interconnects 330 may be considered to be part of the integrated device 303.

The integrated device 305 may be a second integrated device. The integrated device 305 is coupled to the metallization portion 102. For example, the integrated device 305 may be coupled to the metallization portion 102 through a plurality of pillar interconnects 350. The plurality of pillar interconnects 350 may be coupled to and touch the plurality of metallization interconnects 122 of the metallization portion 102. The plurality of pillar interconnects 350 may be coupled to and touch a plurality of pad interconnects of the integrated device 305. The plurality of pillar interconnects 350 may be considered to be part of the integrated device 305.

The integrated device 307 may be a third integrated device. The integrated device 307 is coupled to the metallization portion 102. For example, the integrated device 307 may be coupled to the metallization portion 102 through a plurality of pillar interconnects 370. The plurality of pillar interconnects 370 may be coupled to and touch the plurality of metallization interconnects 122 of the metallization portion 102. The plurality of pillar interconnects 370 may be coupled to and touch a plurality of pad interconnects of the integrated device 307. The plurality of pillar interconnects 370 may be considered to be part of the integrated device 307.

FIG. 3 illustrates that pillar interconnects from the plurality of pillar interconnects 330 may have a first height, pillar interconnects from the plurality of pillar interconnects 350 may have a second height, and pillar interconnects from the plurality of pillar interconnects 370 have a third height. The second height of the plurality of pillar interconnects 350 may be different from the first height of the plurality of pillar interconnects 330. For example, the second height of the plurality of pillar interconnects 350 may be greater from the first height of the plurality of pillar interconnects 330. The third height of the plurality of pillar interconnects 370 may be different from the first height of the plurality of pillar interconnects 330. For example, the third height of the plurality of pillar interconnects 370 may be greater from the first height of the plurality of pillar interconnects 330.

The encapsulation layer 106 may be coupled to the metallization portion 102. The encapsulation layer 106 may at least partially encapsulate the integrated device 303, the integrated device 305, the integrated device 307, the plurality of pillar interconnects 330, the plurality of pillar interconnects 350 and/or the plurality of pillar interconnects 370. The encapsulation layer 106 may include a mold, a resin, an epoxy and/or a filler.

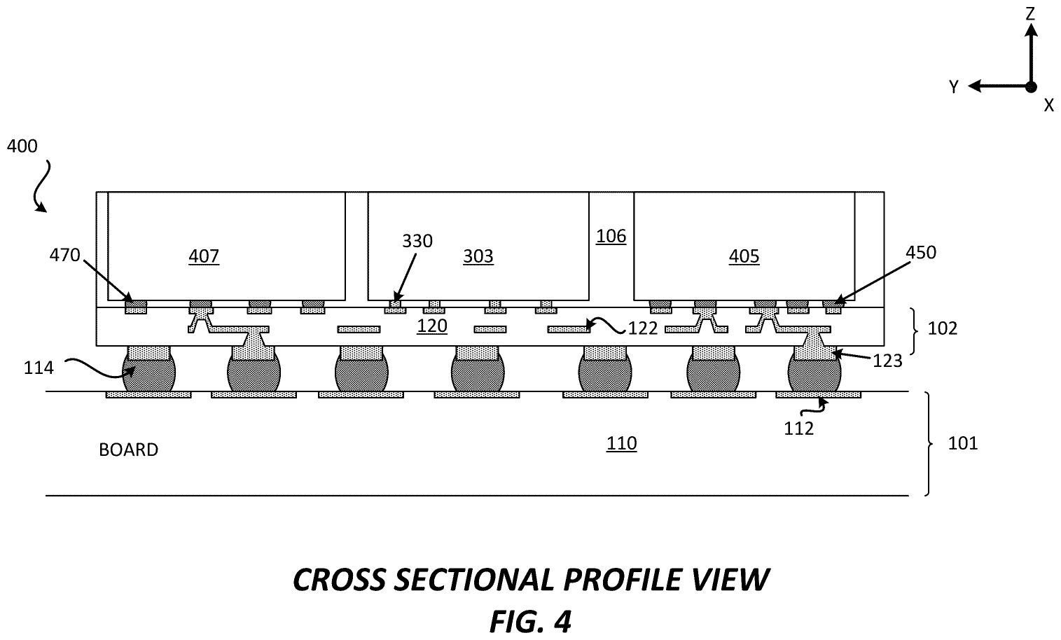

FIG. 4 illustrates a cross sectional profile view of a package 400 that includes integrated devices and a metallization portion. The package 400 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 400 includes a metallization portion 102, an integrated device 303, an integrated device 405, an integrated device 407 and an encapsulation layer 106. The metallization portion 102 includes at least one dielectric layer 120, a plurality of metallization interconnects 122 and a plurality of post interconnects 123. The plurality of post interconnects 123 may be coupled to the plurality of metallization interconnects 122. The plurality of post interconnects 123 may be considered part of the plurality of metallization interconnects 122. The plurality of solder interconnects 114 may be coupled to the plurality of post interconnects 123 and the plurality of board interconnects 112. The plurality of solder interconnects 114 may be coupled to the plurality of metallization interconnects 122.

The integrated device 303 may be a first integrated device. The integrated device 303 is coupled to the metallization portion 102. For example, the integrated device 303 may be coupled to the metallization portion 102 through a plurality of pillar interconnects 330. The plurality of pillar interconnects 330 may be coupled to and touch the plurality of metallization interconnects 122 of the metallization portion 102. The plurality of pillar interconnects 330 may be coupled to and touch a plurality of pad interconnects of the integrated device 303. The plurality of pillar interconnects 330 may be considered to be part of the integrated device 303.

The integrated device 405 may be a second integrated device. The integrated device 405 is coupled to the metallization portion 102. For example, the integrated device 405 may be coupled to the metallization portion 102 through a plurality of solder interconnects 450. The plurality of solder interconnects 450 may be coupled to and touch the plurality of metallization interconnects 122 of the metallization portion 102. The plurality of solder interconnects 450 may be coupled to and touch a plurality of pad interconnects of the integrated device 405.

The integrated device 407 may be a third integrated device. The integrated device 407 is coupled to the metallization portion 102. For example, the integrated device 407 may be coupled to the metallization portion 102 through a plurality of solder interconnects 470. The plurality of solder interconnects 470 may be coupled to and touch the plurality of metallization interconnects 122 of the metallization portion 102. The plurality of solder interconnects 470 may be coupled to and touch a plurality of pad interconnects of the integrated device 407.

The encapsulation layer 106 may be coupled to the metallization portion 102. The encapsulation layer 106 may at least partially encapsulate the integrated device 303, the integrated device 405, the integrated device 407, the plurality of pillar interconnects 330, the plurality of solder interconnects 450 and/or the plurality of solder interconnects 470. The encapsulation layer 106 may include a mold, a resin, an epoxy and/or a filler.

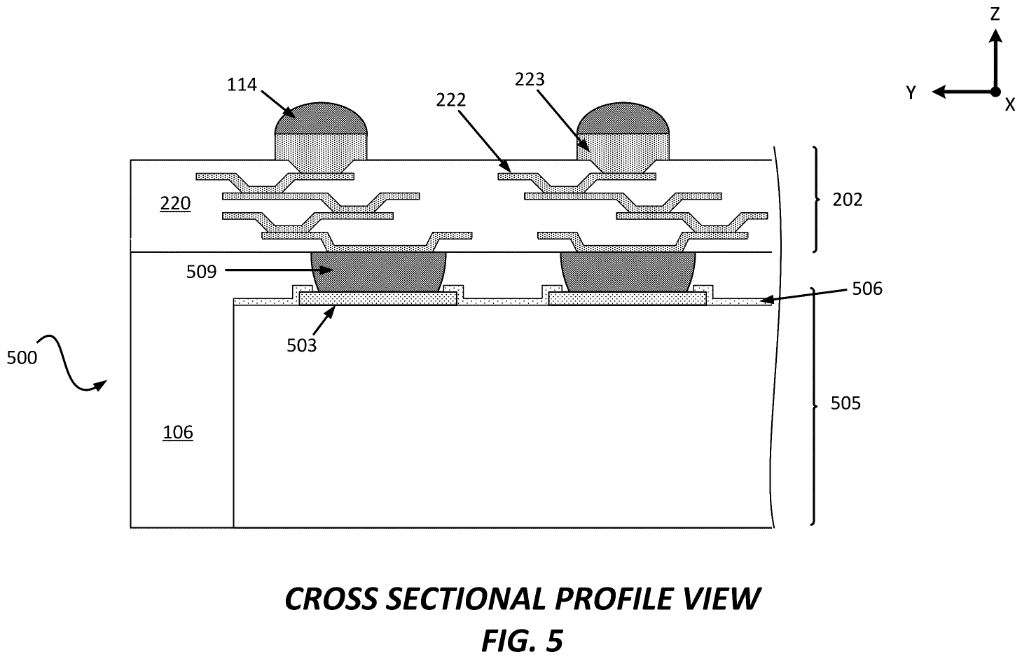

FIG. 5 illustrates a package 500 that includes an integrated device and a metallization portion. In some implementations, the package 500 may be a more detailed representation of a portion of the package 400 of FIG. 4.

The package 500 includes an integrated device 505, a metallization portion 202 and an encapsulation layer 106. The metallization portion 202 includes at least one dielectric layer 220, a plurality of metallization interconnects 222 and a plurality of post interconnects 223. The plurality of post interconnects 223 may be coupled to the plurality of metallization interconnects 222. The plurality of post interconnects 223 may be considered part of the plurality of metallization interconnects 222. A plurality of solder interconnects 114 may be coupled to the plurality of post interconnects 223. The plurality of solder interconnects 114 may be coupled to the plurality of metallization interconnects 222. The encapsulation layer 106 may be coupled to the metallization portion 202. The metallization portion 202 may represent the metallization portion 102.

The integrated device 505 may represent any of the integrated devices described in the disclosure. For example, the integrated device 505 (or a variation) may represent the integrated device 305 and/or the integrated device 307.

The integrated device 505 may be similar to the integrated device 205, and may include similar components as described for the integrated device 205. For example, the integrated device 505 may include a die substrate portion and a die interconnection portion. The die substrate portion may include a die substrate, an active region. The active region may include a plurality of logic cells, a plurality of transistors, and/or a plurality of filters. The die substrate may include silicon (Si). The die substrate may comprise a bulk silicon. The bulk silicon may include a monolith silicon. Different implementations may have different thicknesses for the die substrate. The die interconnection portion includes at least one dielectric layer and a plurality of die interconnects. The die interconnection portion is coupled to the die substrate portion. The plurality of die interconnects are coupled to the active region of the die substrate portion. The integrated device 505 may include a passivation layer 506 and a plurality of pad interconnects 503. The plurality of pad interconnects 503 may be coupled to the plurality of die interconnects.

The integrated device 505 is coupled to the metallization portion 202. For example, the integrated device 505 is coupled to the metallization portion 202 through the plurality of solder interconnects 509. The plurality of solder interconnects 509 may be coupled to and touch the plurality of metallization interconnects 222 of the metallization portion 202. The plurality of solder interconnects 509 may be coupled to and touch the plurality of pad interconnects 503 of the integrated device 505.

In some implementations, an electrical path to and/or from an active region may include at least one die interconnect from the plurality of die interconnects, at least one pad interconnect from the plurality of pad interconnects 503, at least one solder interconnect from the plurality of solder interconnects 509, at least one metallization interconnect from the plurality of metallization interconnects 222, at least one post interconnect from the plurality of post interconnects 223 and/or at least one solder interconnect from the plurality of solder interconnects 114.

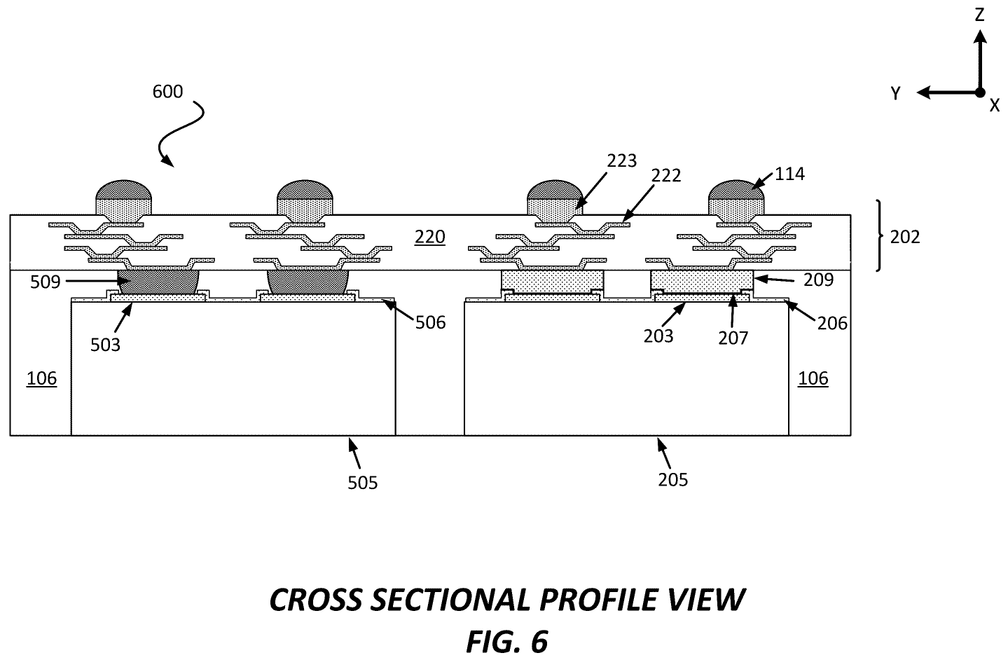

FIG. 6 illustrates a package 600 that includes integrated devices and a metallization portion. The package 600 includes a metallization portion 202, an integrated device 205, an integrated device 505 and an encapsulation layer 106. The metallization portion 202 includes at least one dielectric layer 220, a plurality of metallization interconnects 222 and a plurality of post interconnects 223. The plurality of solder interconnects 114 are coupled to the plurality of post interconnects 223. The plurality of solder interconnects 114 may be coupled to the plurality of metallization interconnects 222. In some implementations, the plurality of post interconnects 223 may be considered part of the plurality of metallization interconnects 222.

The integrated device 205 is coupled to the metallization portion 202 through a plurality of pillar interconnects 209. The plurality of pillar interconnects 209 may be coupled to and touch the plurality of metallization interconnects 222.

The integrated device 505 is coupled to the metallization portion 202 through a plurality of solder interconnects 509. The plurality of solder interconnects 509 may be coupled to and touch the plurality of metallization interconnects 222.

The encapsulation layer 106 may at least partially encapsulate the integrated device 205, the integrated device 505, the plurality of pillar interconnects 209 and/or the plurality of solder interconnects 509. The encapsulation layer 106 may be coupled to the metallization portion 202.

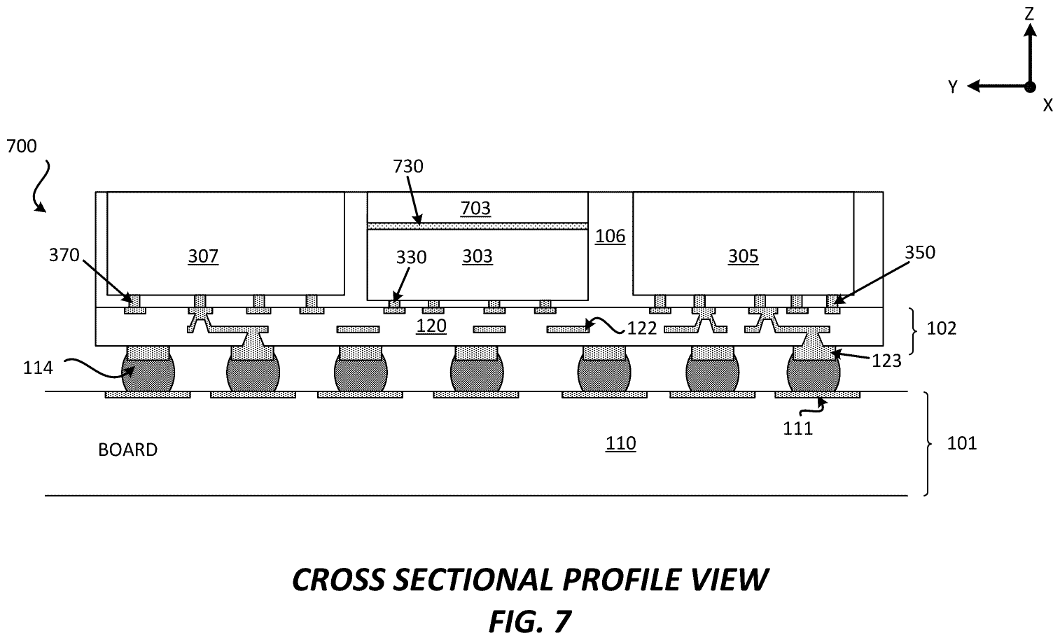

FIG. 7 illustrates a cross sectional profile view of a package 700 that includes integrated devices, a metallization portion and a dummy silicon structure. The package 700 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 700 may be similar to the package 300, and may include similar components as the package 300. The package 700 includes a metallization portion 102, an integrated device 303, an integrated device 305, an integrated device 307, an encapsulation layer 106 and a dummy silicon structure 703. The metallization portion 102 includes at least one dielectric layer 120, a plurality of metallization interconnects 122 and a plurality of post interconnects 123. The plurality of post interconnects 123 may be coupled to the plurality of metallization interconnects 122. The plurality of post interconnects 123 may be considered part of the plurality of metallization interconnects 122. The plurality of solder interconnects 114 may be coupled to the plurality of post interconnects 123 and the plurality of board interconnects 112. The plurality of solder interconnects 114 may be coupled to the plurality of metallization interconnects 122.

The integrated device 303 may be a first integrated device. The integrated device 303 is coupled to the metallization portion 102. For example, the integrated device 303 may be coupled to the metallization portion 102 through a plurality of pillar interconnects 330. The plurality of pillar interconnects 330 may be coupled to and touch the plurality of metallization interconnects 122 of the metallization portion 102. The plurality of pillar interconnects 330 may be coupled to and touch a plurality of pad interconnects of the integrated device 303. The plurality of pillar interconnects 330 may be considered to be part of the integrated device 303. The dummy silicon structure 703 is coupled to a back side of the integrated device 303 through an adhesive 730. The adhesive 730 may include a die attach film (DAF).

The integrated device 305 may be a second integrated device. The integrated device 305 is coupled to the metallization portion 102. For example, the integrated device 305 may be coupled to the metallization portion 102 through a plurality of pillar interconnects 350. The plurality of pillar interconnects 350 may be coupled to and touch the plurality of metallization interconnects 122 of the metallization portion 102. The plurality of pillar interconnects 350 may be coupled to and touch a plurality of pad interconnects of the integrated device 305. The plurality of pillar interconnects 350 may be considered to be part of the integrated device 305.

The integrated device 307 may be a third integrated device. The integrated device 307 is coupled to the metallization portion 102. For example, the integrated device 307 may be coupled to the metallization portion 102 through a plurality of pillar interconnects 370. The plurality of pillar interconnects 370 may be coupled to and touch the plurality of metallization interconnects 122 of the metallization portion 102. The plurality of pillar interconnects 370 may be coupled to and touch a plurality of pad interconnects of the integrated device 307. The plurality of pillar interconnects 370 may be considered to be part of the integrated device 307.

The encapsulation layer 106 may be coupled to the metallization portion 102. The encapsulation layer 106 may at least partially encapsulate the integrated device 303, the integrated device 305, the integrated device 307, the dummy silicon structure 703, the adhesive 730, the plurality of pillar interconnects 330, the plurality of pillar interconnects 350 and/or the plurality of pillar interconnects 370. The encapsulation layer 106 may include a mold, a resin, an epoxy and/or a filler.

The dummy silicon structure 703 may be configured to be free of any electrical connection with circuits and/or active regions of an integrated device. In some implementations, instead of a dummy silicon structure, a heat sink may be coupled to the back side of the integrated device 303. A thermal interface material (TIM) may be used to couple the heat sink to the integrated device 303. A heat sink may include a copper slug.

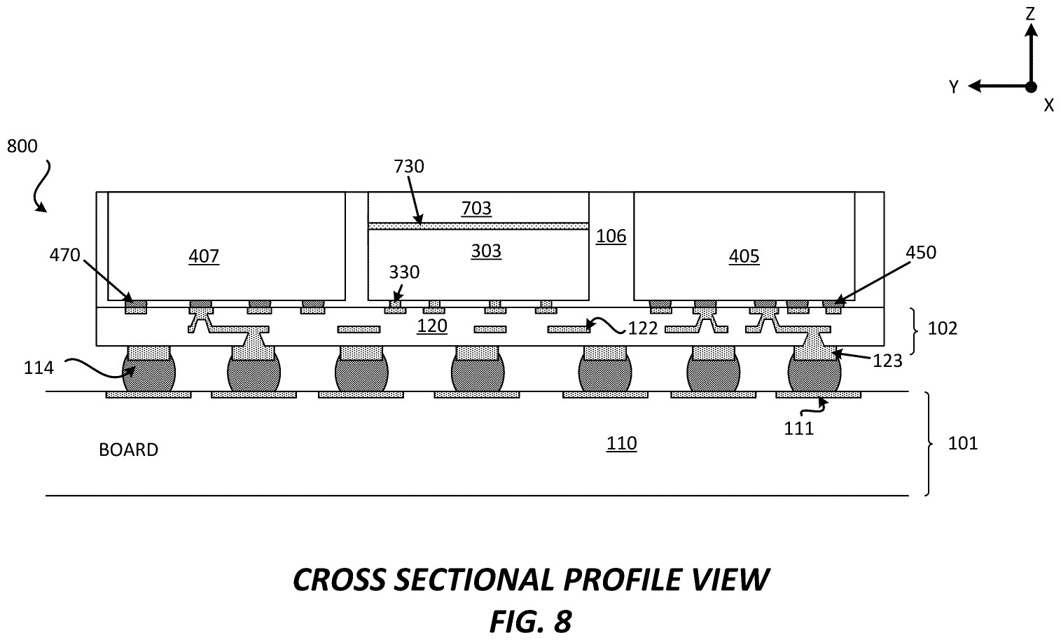

FIG. 8 illustrates a cross sectional profile view of a package 800 that includes integrated devices, a metallization portion and a dummy silicon structure. The package 800 is coupled to a board 101 through a plurality of solder interconnects 114. The board 101 includes at least one board dielectric layer 110 and a plurality of board interconnects 112. The board 101 may include a printed circuit board (PCB). In some implementations, the package 100 may be coupled to a substrate instead of the board 101.

The package 800 may be similar to the package 400, and may include similar components as the package 400. The package 800 includes a metallization portion 102, an integrated device 303, an integrated device 405, an integrated device 407, an encapsulation layer 106 and a dummy silicon structure 703. The metallization portion 102 includes at least one dielectric layer 120, a plurality of metallization interconnects 122 and a plurality of post interconnects 123. The plurality of post interconnects 123 may be coupled to the plurality of metallization interconnects 122. The plurality of post interconnects 123 may be considered part of the plurality of metallization interconnects 122. The plurality of solder interconnects 114 may be coupled to the plurality of post interconnects 123 and the plurality of board interconnects 112. The plurality of solder interconnects 114 may be coupled to the plurality of metallization interconnects 122.

The integrated device 303 may be a first integrated device. The integrated device 303 is coupled to the metallization portion 102. For example, the integrated device 303 may be coupled to the metallization portion 102 through a plurality of pillar interconnects 330. The plurality of pillar interconnects 330 may be coupled to and touch the plurality of metallization interconnects 122 of the metallization portion 102. The plurality of pillar interconnects 330 may be coupled to and touch a plurality of pad interconnects of the integrated device 303. The plurality of pillar interconnects 330 may be considered to be part of the integrated device 303. The dummy silicon structure 703 is coupled to a back side of the integrated device 303 through an adhesive 730. The adhesive 730 may include a die attach film (DAF).

The integrated device 405 may be a second integrated device. The integrated device 405 is coupled to the metallization portion 102. For example, the integrated device 405 may be coupled to the metallization portion 102 through a plurality of solder interconnects 450. The plurality of solder interconnects 450 may be coupled to and touch the plurality of metallization interconnects 122 of the metallization portion 102. The plurality of solder interconnects 450 may be coupled to and touch a plurality of pad interconnects of the integrated device 405.

The integrated device 407 may be a third integrated device. The integrated device 407 is coupled to the metallization portion 102. For example, the integrated device 407 may be coupled to the metallization portion 102 through a plurality of solder interconnects 470. The plurality of solder interconnects 470 may be coupled to and touch the plurality of metallization interconnects 122 of the metallization portion 102. The plurality of solder interconnects 470 may be coupled to and touch a plurality of pad interconnects of the integrated device 407.

The encapsulation layer 106 may be coupled to the metallization portion 102. The encapsulation layer 106 may at least partially encapsulate the integrated device 303, the integrated device 405, the integrated device 407, the dummy silicon structure 703, the adhesive 730, the plurality of pillar interconnects 330, the plurality of solder interconnects 450 and/or the plurality of solder interconnects 470. The encapsulation layer 106 may include a mold, a resin, an epoxy and/or a filler.

The dummy silicon structure 703 may be configured to be free of any electrical connection with circuits and/or active regions of an integrated device. In some implementations, instead of a dummy silicon structure, a heat sink may be coupled to the back side of the integrated device 303. A thermal interface material (TIM) may be used to couple the heat sink to the integrated device 303. A heat sink may include a copper slug.

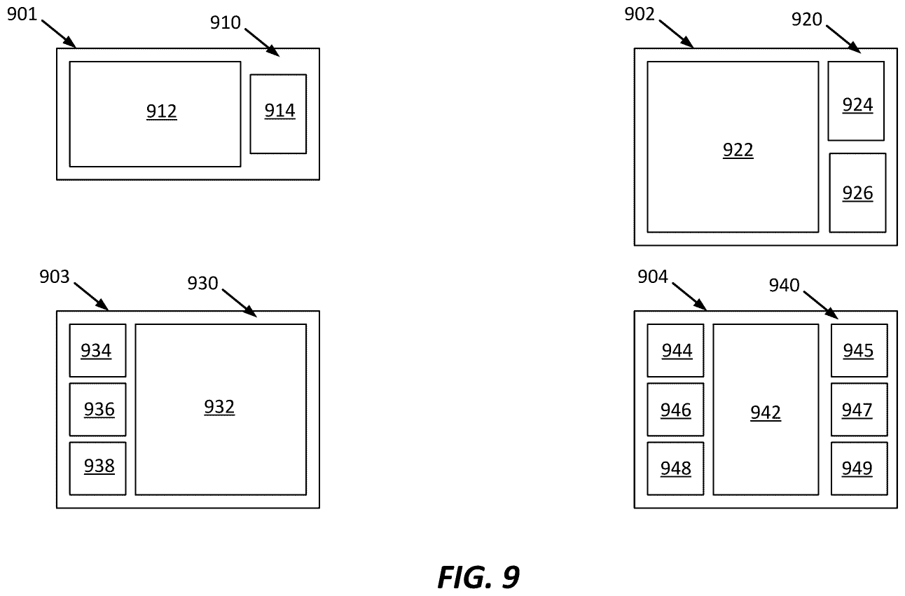

FIG. 9 illustrates various configuration of packages that may include several integrated devices, a metallization portion and an encapsulation layer. FIG. 9 illustrates plan view of a package 901, a package 902, a package 903 and a package 904. The package 901, the package 902, the package 903 and/or the package 904 may be represented by any of the packages shown in FIGS. 1-8.

The package 901 includes an integrated device 912, an integrated device 914, an encapsulation layer 910 and a metallization portion (not shown). The encapsulation layer 910 may at least partially encapsulate the integrated device 912 and the integrated device 914. The integrated device 912 may include a system on chip (SoC). The integrated device 914 may include a memory device (e.g., double data rate (DDR) memory).

The package 902 includes an integrated device 922, an integrated device 924, an integrated device 926, an encapsulation layer 920 and a metallization portion (not shown). The encapsulation layer 920 may at least partially encapsulate the integrated device 922, the integrated device 924 and the integrated device 926. The integrated device 922 may include a system on chip (SoC). The integrated device 924 may include a first memory device (e.g., first double data rate (DDR) memory). The integrated device 926 may include a second memory device (e.g., second double data rate (DDR) memory).

The package 903 includes an integrated device 932, an integrated device 934, an integrated device 936, an integrated device 938, an encapsulation layer 930 and a metallization portion (not shown). The encapsulation layer 930 may at least partially encapsulate the integrated device 932, the integrated device 934, the integrated device 936 and the integrated device 938. The integrated device 932 may include a system on chip (SoC). The integrated device 934 may include a first memory device (e.g., first high bandwidth memory (HBM)). The integrated device 936 may include a second memory device (e.g., second high bandwidth memory (HBM)). The integrated device 938 may include a third memory device (e.g., third high bandwidth memory (HBM)).

The package 904 includes an integrated device 942, an integrated device 944, an integrated device 945, an integrated device 946, an integrated device 947, an integrated device 948, an integrated device 949, an encapsulation layer 940 and a metallization portion (not shown). The encapsulation layer 930 may at least partially encapsulate the integrated device 942, the integrated device 944, the integrated device 945, integrated device 946, the integrated device 947, the integrated device 948, the integrated device 949. The integrated device 942 may include a system on chip (SoC). The integrated device 944 may include a memory device (e.g., high bandwidth memory (HBM)). The integrated device 945 may include a memory device (e.g., high bandwidth memory (HBM)). The integrated device 946 may include a memory device (e.g., high bandwidth memory (HBM)). The integrated device 947 may include a memory device (e.g., high bandwidth memory (HBM)). The integrated device 948 may include a memory device (e.g., high bandwidth memory (HBM)). The integrated device 949 may include a memory device (e.g., high bandwidth memory (HBM)). The integrated device 944, the integrated device 946 and the integrated device 948 may be located adjacent to one side of the integrated device 942. The integrated device 945, the integrated device 947 and the integrated device 949 may be located adjacent to another side of the integrated device 942.

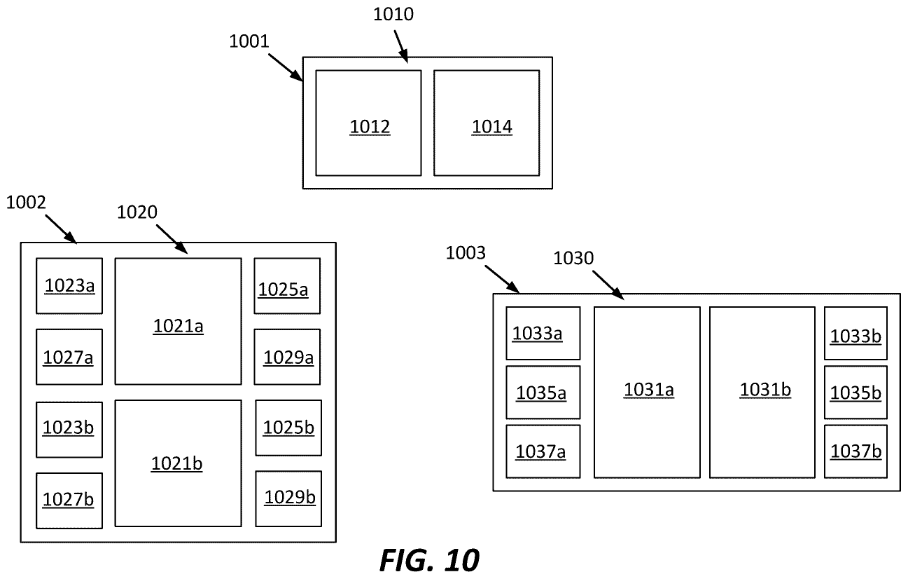

FIG. 10 illustrates various configuration of packages that may include several integrated devices, a metallization portion and an encapsulation layer. FIG. 10 illustrates plan views of a package 1001, a package 1002 and a package 1003. The package 1001, the package 1002 and/or the package 1003 may be represented by any of the packages shown in FIGS. 1-8.

The package 1001 includes an integrated device 1012, an integrated device 1014, an encapsulation layer 1010 and a metallization portion (not shown). The encapsulation layer 1010 may at least partially encapsulate the integrated device 1012 and the integrated device 1014. The integrated device 1012 may include a first system on chip (SoC). The integrated device 1014 may include a second system on chip (SoC).

The package 1002 includes an integrated device 1021a, an integrated device 1021b, an integrated device 1023a, an integrated device 1025a, an integrated device 1027a, an integrated device 1029a, an integrated device 1023b, an integrated device 1025b, an integrated device 1027b, an integrated device 1029b, and an encapsulation layer 1020 and a metallization portion (not shown). The encapsulation layer 1020 may at least partially encapsulate the integrated device 1021a, the integrated device 1021b, the integrated device 1023a, the integrated device 1025a, the integrated device 1027a, the integrated device 1029a, the integrated device 1023b, the integrated device 1025b, the integrated device 1027b and/or the integrated device 1029b. The integrated device 1021a may include a first system on chip (SoC). The integrated device 1021b may include a second system on chip (SoC). The integrated device 1023a may include a memory device (e.g., high bandwidth memory (HBM)). The integrated device 1025a may include a memory device (e.g., high bandwidth memory (HBM)). The integrated device 1027a may include a memory device (e.g., high bandwidth memory (HBM)). The integrated device 1029a may include a memory device (e.g., high bandwidth memory (HBM)). The integrated device 1023b may include a memory device (e.g., high bandwidth memory (HBM)). The integrated device 1025b may include a memory device (e.g., high bandwidth memory (HBM)). The integrated device 1027b may include a memory device (e.g., high bandwidth memory (HBM)). The integrated device 1029b may include a memory device (e.g., high bandwidth memory (HBM)). The integrated device 1023a and the integrated device 1027a may be located adjacent to one side of the integrated device 1021a. The integrated device 1025a and the integrated device 1029a may be located adjacent to another side of the integrated device 1021a. The integrated device 1023b and the integrated device 1027b may be located adjacent to one side of the integrated device 1021b. The integrated device 1025b and the integrated device 1029b may be located adjacent to another side of the integrated device 1021b.

The package 1003 includes an integrated device 1031a, an integrated device 1031b, an integrated device 1033a, an integrated device 1035a, an integrated device 1037a, an integrated device 1033b, an integrated device 1035b, an integrated device 1037b, and an encapsulation layer 1030 and a metallization portion (not shown). The encapsulation layer 1030 may at least partially encapsulate the integrated device 1031a, the integrated device 1031b, the integrated device 1033a, the integrated device 1035a, the integrated device 1037a, the integrated device 1033b, the integrated device 1035b and/or the integrated device 1037b. The integrated device 1031a may include a first system on chip (SoC). The integrated device 1031b may include a second system on chip (SoC). The integrated device 1033a may include a memory device (e.g., high bandwidth memory (HBM)). The integrated device 1035a may include a memory device (e.g., high bandwidth memory (HBM)). The integrated device 1037a may include a memory device (e.g., high bandwidth memory (HBM)). The integrated device 1033b may include a memory device (e.g., high bandwidth memory (HBM)). The integrated device 1035b may include a memory device (e.g., high bandwidth memory (HBM)). The integrated device 1037b may include a memory device (e.g., high bandwidth memory (HBM)). The integrated device 1033a, the integrated device 1035a and the integrated device 1037a may be located adjacent to one side of the integrated device 1031a. The integrated device 1033b, the integrated device 1035b and the integrated device 1037b may be located adjacent to one side of the integrated device 1031b.

FIGS. 1-10 illustrate examples of packages that include various configurations of integrated devices that are close to each other. This provides short electrical paths between integrated devices (e.g., between a processor and a memory), which may allow for high performance of the package. The packages may be packages with high reliability, high performance, low power consumption and/or reduced latency.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc.,). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 200) may be configured to provide Wireless Fidelity (WiFi) communication and/or cellular communication (e.g., 2G, 3G, 4G, 5G). The packages (e.g., 200, 600) may be configured to support Global System for Mobile (GSM) Communications, Universal Mobile Telecommunications System (UMTS), and/or Long-Term Evolution (LTE). The packages (e.g., 200) may be configured to transmit and receive signals having different frequencies and/or communication protocols.

### Exemplary Sequence for Fabricating a Package

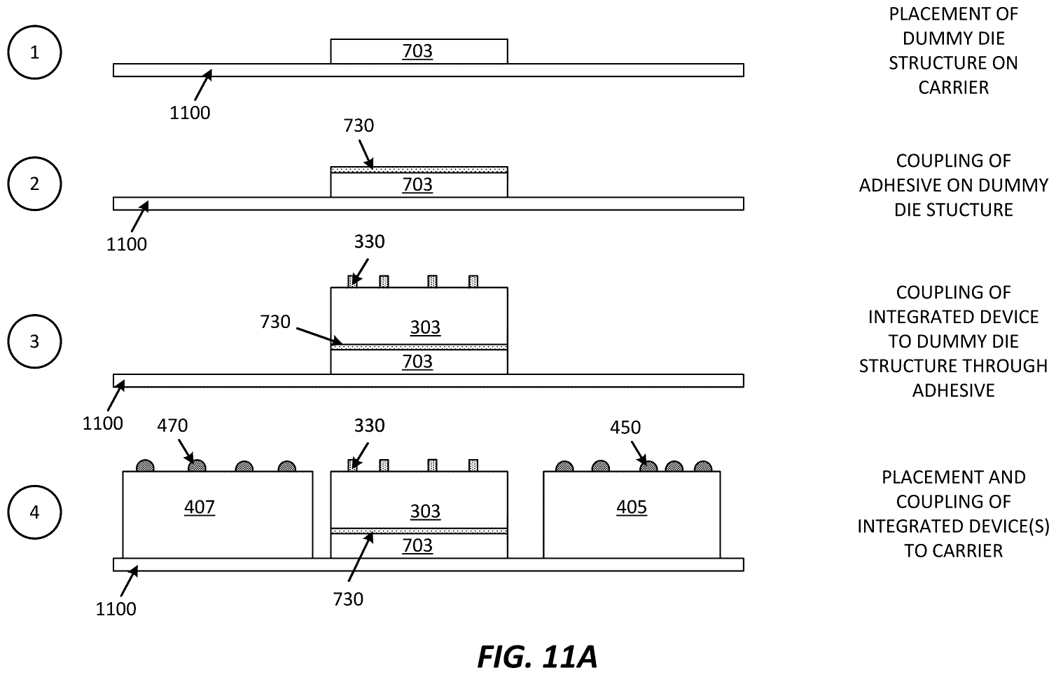

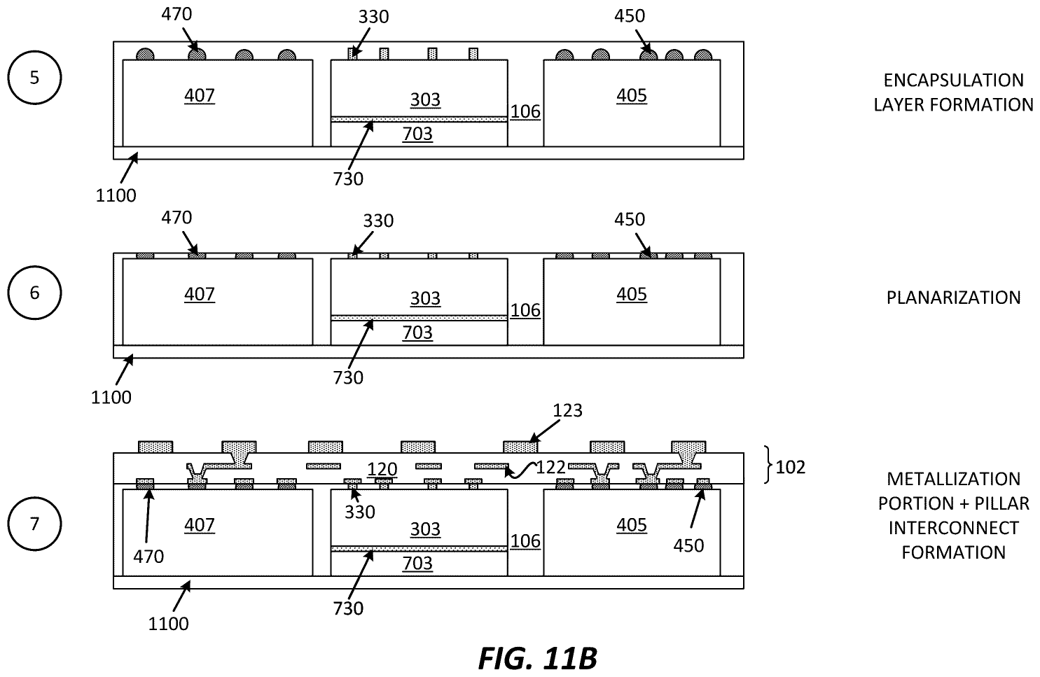

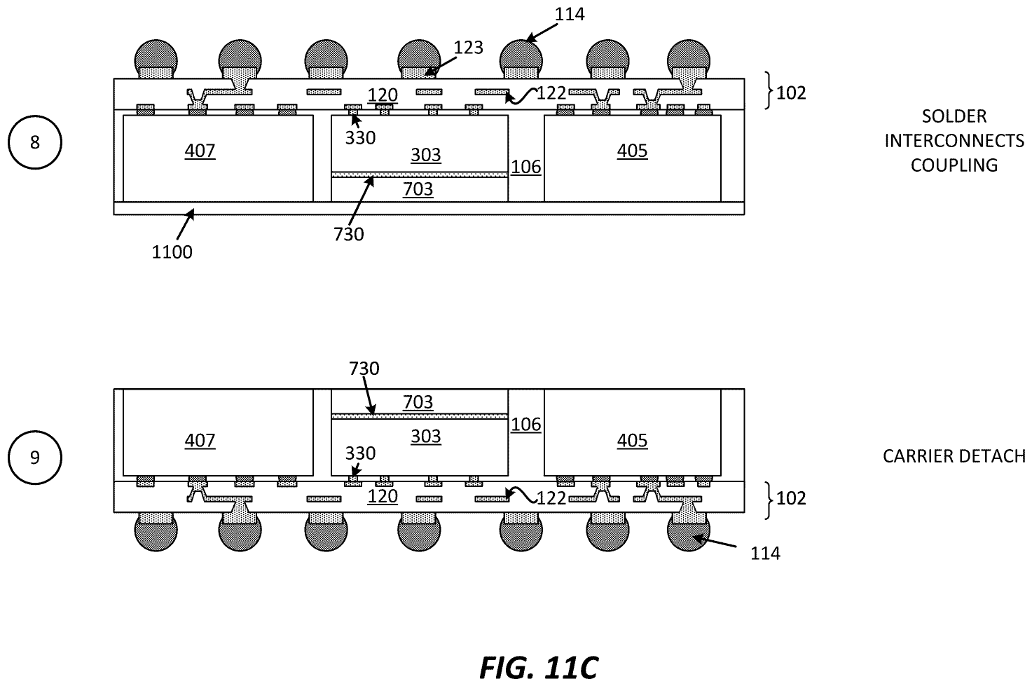

In some implementations, fabricating a package includes several processes. FIGS. 11A-11C illustrate an exemplary sequence for providing or fabricating a package. In some implementations, the sequence of FIGS. 11A-11C may be used to provide or fabricate the package 800. However, the process of FIGS. 11A-11C may be used to fabricate any of the packages described in the disclosure.

It should be noted that the sequence of FIGS. 11A-11C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 11A, illustrates a state after a dummy silicon structure 703 is provided, placed and/or coupled to a carrier 1100. The carrier 1100 may include glass. An adhesive may be used to place and couple the dummy silicon structure 703 to the carrier 1000. Instead of and/or in conjunction to a dummy silicon structure 703, a heat sink may be provided, placed and/or coupled to the carrier 1100. An adhesive may be used to place and couple the heat sink to the carrier 1100.

Stage 2 illustrates a state after an adhesive 730 is disposed over the dummy silicon structure 703. The adhesive 730 may include a die attach film (DAF). In some implementations, instead of an adhesive, a thermal interface material (TIM) may be disposed over the dummy silicon structure 703.

Stage 3 illustrates a state after an integrated device 303 is coupled to the dummy silicon structure 703 through the adhesive 730. The adhesive 730 is coupled to and touches a back side of the integrated device 303. The integrated device 303 may include a plurality of pillar interconnects 330.

Stage 4 illustrates a state after an integrated device 405 is provided, placed and/or coupled to the carrier 1100. An adhesive may be used to couple a back side of the integrated device 405 to the carrier 1100. A plurality of solder interconnects 450 may be coupled to a front side of the integrated device 405. Stage 4 also illustrates a state after an integrated device 407 is provided, placed and/or coupled to the carrier 1100. An adhesive may be used to couple a back side of the integrated device 407 to the carrier 1100. A plurality of solder interconnects 470 may be coupled to a front side of the integrated device 407.

Stage 5, as shown in FIG. 11B, illustrates a state after an encapsulation layer 106 is coupled the carrier 1100. The encapsulation layer 106 may be formed such that the encapsulation layer 106 at least partially encapsulates the dummy silicon structure 703, the integrated device 303, the integrated device 405, the integrated device 407, the adhesive 730, the plurality of pillar interconnects 330, the plurality of solder interconnects 450 and/or the plurality of solder interconnects 470. The encapsulation layer 106 may include a mold, a resin, an epoxy and/or a filler. The encapsulation layer 106 may be provided by using a compression and transfer molding process, a sheet molding process, or a liquid molding process.

Stage 6 illustrates a state after a planarization of the encapsulation layer 106. A portion of the encapsulation layer 106 may be removed. A portion of the plurality of pillar interconnects 330 may be removed. A portion of the plurality of solder interconnects 450 may be removed. A portion of the plurality of solder interconnects 470 may be removed. A grinding process may be used to planarize the encapsulation layer 106, the plurality of pillar interconnects 330, the plurality of solder interconnects 450 and the plurality of solder interconnects 470.

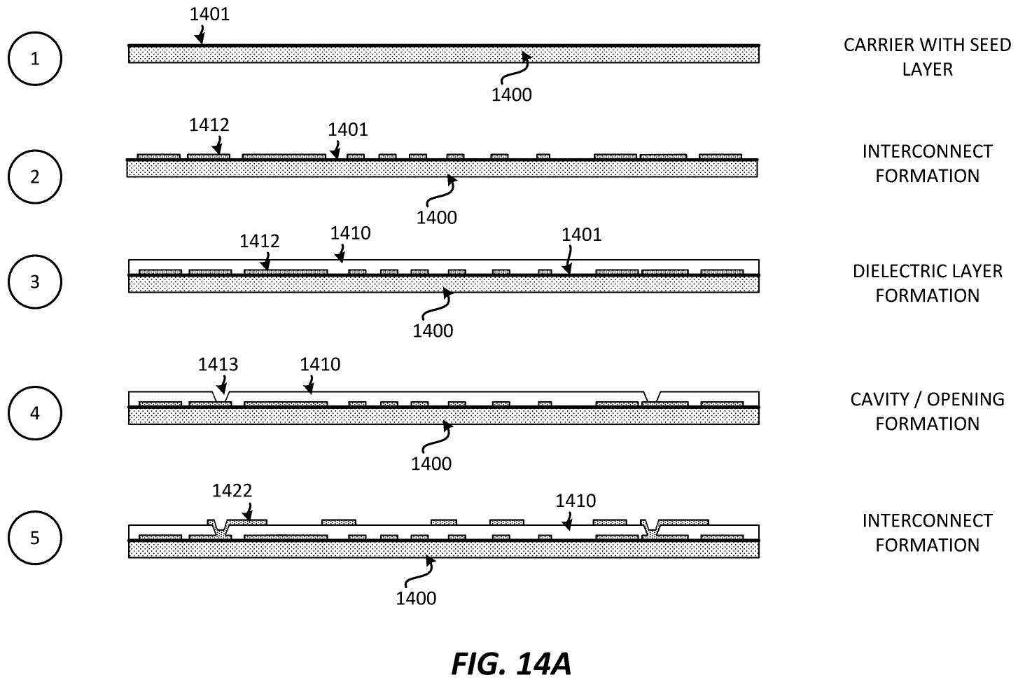

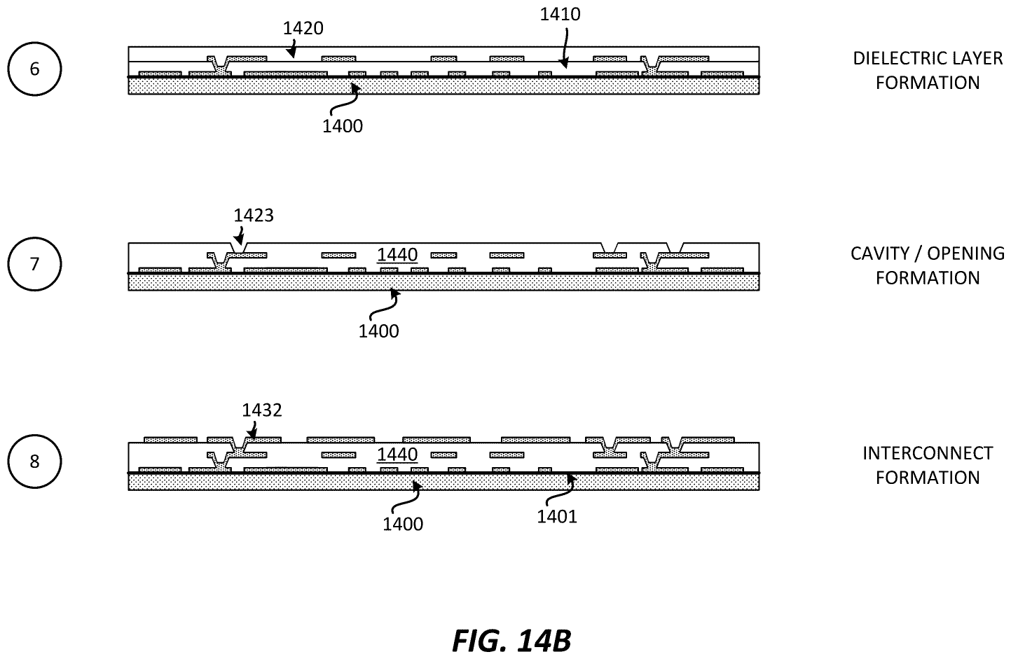

Stage 7 illustrates a state after a metallization portion 102 is formed and coupled to the plurality of pillar interconnects 330, the plurality of solder interconnects 450, the plurality of solder interconnects 470 and the encapsulation layer 106. In some implementations, forming the metallization portion 102 includes forming at least one dielectric layer 120, a plurality of metallization interconnects 122 and a plurality of post interconnects 123. The plurality of metallization interconnects 122 may be coupled to and touch the plurality of pillar interconnects 330, the plurality of solder interconnects 450 and the plurality of solder interconnects 470. In some implementations, a deposition process, a lamination process, an etching process (e.g., photo etching process), a laser process, an exposure process, a development process, a lithography process, a plating process, and/or a strip process may be used to form the metallization portion 102. An example of forming a metallization portion is illustrated and described below in at least FIGS. 14A-14B.

Stage 8 of FIG. 11C, illustrates a state after a plurality of solder interconnects 114 are coupled to the metallization portion 102. A solder reflow process may be used to couple the plurality of solder interconnects 114 to the plurality of post interconnects 123 of the metallization portion 102.

Stage 9 illustrates a state after the carrier 1100 is detached from the encapsulation layer 106, the integrated device 405, the integrated device 407 and the dummy silicon structure 703. Stage 9 may illustrates a package 800 of FIG. 8.

### Exemplary Sequence for Fabricating a Package

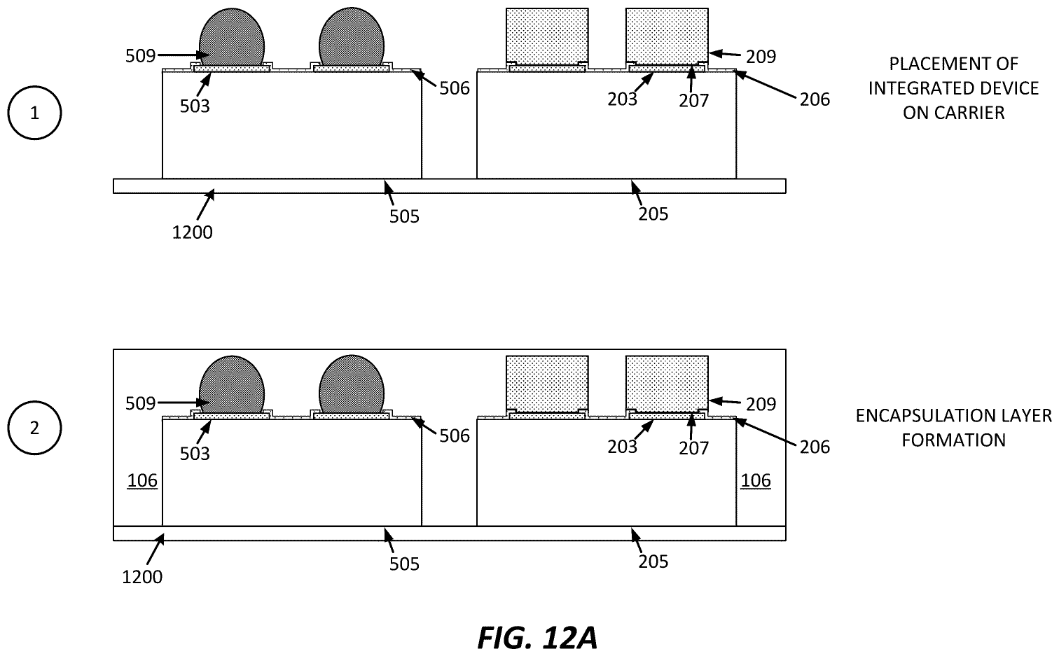

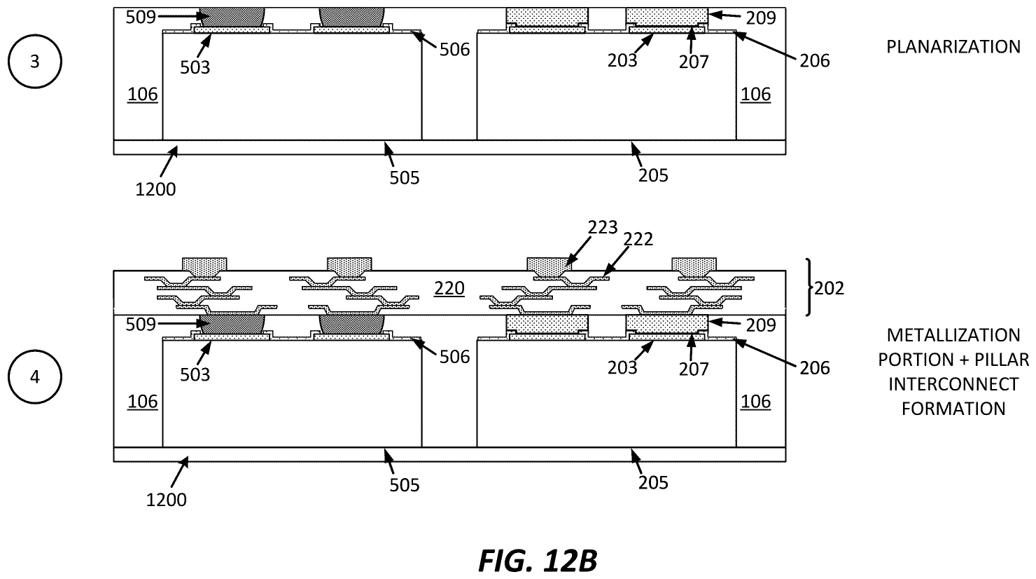

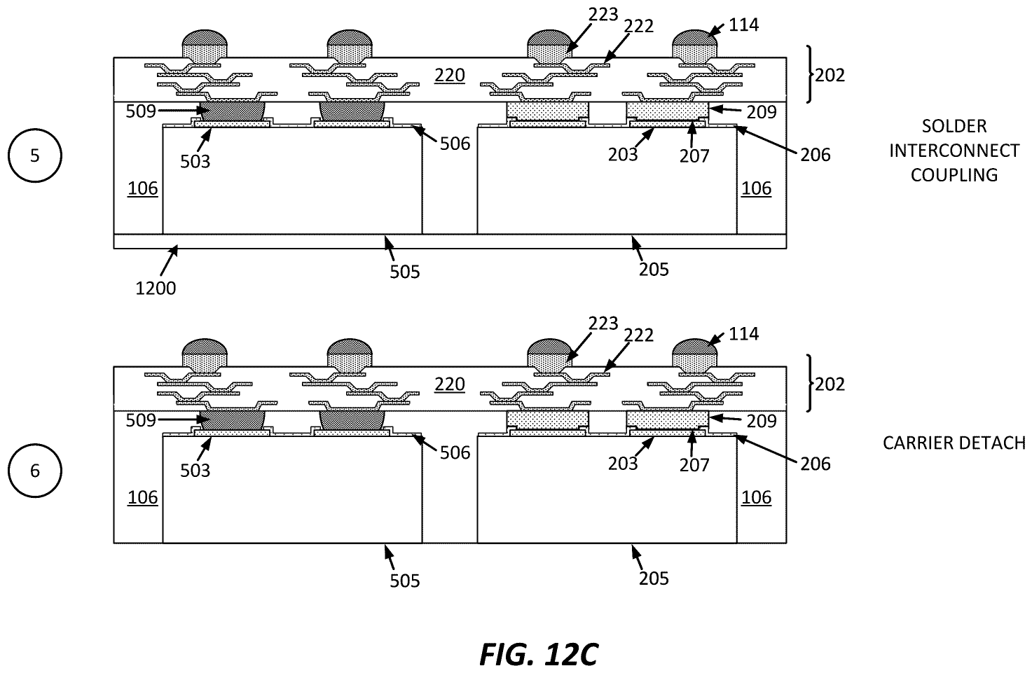

In some implementations, fabricating a package includes several processes. FIGS. 12A-12C illustrate an exemplary sequence for providing or fabricating a package. In some implementations, the sequence of FIGS. 12A-12C may be used to provide or fabricate the package 600. However, the process of FIGS. 12A-12C may be used to fabricate any of the packages described in the disclosure.

It should be noted that the sequence of FIGS. 12A-12C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 12A, illustrates a state after an integrated device 205 and an integrated device 505 are provided, placed and/or coupled to a carrier 1200. The carrier 1200 may include glass. An adhesive may be used to place and couple the integrated device 205 and the integrated device 505 to the carrier 1200. The integrated device 205 may include a plurality of pillar interconnects 209. The integrated device 505 may include a plurality of solder interconnects 509.

Stage 2 illustrates a state after an encapsulation layer 106 is coupled the carrier 1200. The encapsulation layer 106 may be formed such that the encapsulation layer 106 at least partially encapsulates the integrated device 205, the integrated device 505, the plurality of pillar interconnects 209 and the plurality of solder interconnects 509. The encapsulation layer 106 may include a mold, a resin, an epoxy and/or a filler. The encapsulation layer 106 may be provided by using a compression and transfer molding process, a sheet molding process, or a liquid molding process.

Stage 3, as shown in FIG. 12B, illustrates a state after a planarization of the encapsulation layer 106. A portion of the encapsulation layer 106 may be removed. A portion of the plurality of pillar interconnects 209 may be removed. A portion of the plurality of solder interconnects 509 may be removed. A grinding process may be used to planarize the encapsulation layer 106, the plurality of pillar interconnects 209 and the plurality of solder interconnects 509.

Stage 4 illustrates a state after a metallization portion 202 is formed and coupled to the plurality of pillar interconnects 209, the plurality of solder interconnects 509 and the encapsulation layer 106. In some implementations, forming the metallization portion 202 includes forming at least one dielectric layer 220, a plurality of metallization interconnects 222 and a plurality of post interconnects 223. The plurality of metallization interconnects 222 may be coupled to and touch the plurality of pillar interconnects 209 and the plurality of solder interconnects 509. In some implementations, a deposition process, a lamination process, an etching process (e.g., photo etching process), a laser process, an exposure process, a development process, a lithography process, a plating process, and/or a strip process may be used to form the metallization portion 202. An example of forming a metallization portion is illustrated and described below in at least FIGS. 14A-14B.

Stage 5 of FIG. 12C, illustrates a state after a plurality of solder interconnects 114 are coupled to the metallization portion 202. A solder reflow process may be used to couple the plurality of solder interconnects 114 to the plurality of post interconnects 223 of the metallization portion 202.

Stage 6 illustrates a state after the carrier 1200 is detached from the encapsulation layer 106, the integrated device 205 and the integrated device 505. Stage 9 may illustrates a package 600 of FIG. 6.

### Exemplary Flow Diagram of a Method for Fabricating a Package

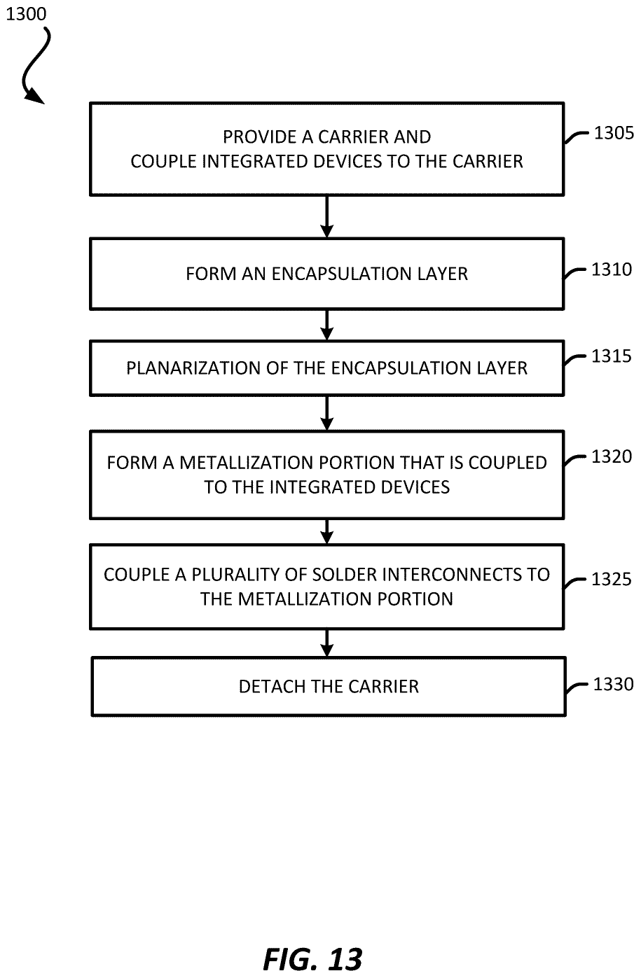

In some implementations, fabricating a package includes several processes. FIG. 13 illustrates an exemplary flow diagram of a method 1300 for providing or fabricating a package. In some implementations, the method 1300 of FIG. 13 may be used to provide or fabricate any of the packages described in the disclosure.

It should be noted that the method 1300 of FIG. 13 may combine one or more processes in order to simplify and/or clarify the method for providing or fabricating a package. In some implementations, the order of the processes may be changed or modified.

The method provides (at 1305) a carrier and couples integrated devices to the carrier. Stage 1 of FIG. 12A, illustrates and describes an example of a state after an integrated device 205 and an integrated device 505 are provided, placed and/or coupled to a carrier 1200. The carrier 1200 may include glass. An adhesive may be used to place and couple the integrated device 205 and the integrated device 505 to the carrier 1200. The integrated device 205 may include a plurality of pillar interconnects 209. The integrated device 505 may include a plurality of solder interconnects 509.

The method forms (at 1310) an encapsulation layer. Stage 2 of FIG. 12A, illustrates and describes an example of a state after an encapsulation layer 106 is coupled the carrier 1200. The encapsulation layer 106 may be formed such that the encapsulation layer 106 at least partially encapsulates the integrated device 205, the integrated device 505, the plurality of pillar interconnects 209 and the plurality of solder interconnects 509. The encapsulation layer 106 may include a mold, a resin, an epoxy and/or a filler. The encapsulation layer 106 may be provided by using a compression and transfer molding process, a sheet molding process, or a liquid molding process.

The method planarizes (at 1315) the encapsulation layer. Stage 3 of FIG. 12B, illustrates and describes an example of a state after a planarization of the encapsulation layer 106. A portion of the encapsulation layer 106 may be removed. A portion of the plurality of pillar interconnects 209 may be removed. A portion of the plurality of solder interconnects 509 may be removed. A grinding process may be used to planarize the encapsulation layer 106, the plurality of pillar interconnects 209 and the plurality of solder interconnects 509.

The method forms (at 1320) a metallization portion that is coupled to the integrated devices. Stage 4 of FIG. 12B, illustrates and describes an example of a state after a metallization portion 202 is formed and coupled to the plurality of pillar interconnects 209, the plurality of solder interconnects 509 and the encapsulation layer 106. In some implementations, forming the metallization portion 202 includes forming at least one dielectric layer 220, a plurality of metallization interconnects 222 and a plurality of post interconnects 223. The plurality of metallization interconnects 222 may be coupled to and touch the plurality of pillar interconnects 209 and the plurality of solder interconnects 509. In some implementations, a deposition process, a lamination process, an etching process (e.g., photo etching process), a laser process, an exposure process, a development process, a lithography process, a plating process, and/or a strip process may be used to form the metallization portion 202. An example of forming a metallization portion is illustrated and described below in at least FIGS. 14A-14B.

The method couples (at 1325) a plurality of solder interconnects to the metallization portion. Stage 5 of FIG. 12C, illustrates and describes an example of a state after a plurality of solder interconnects 114 are coupled to the metallization portion 202. A solder reflow process may be used to couple the plurality of solder interconnects 114 to the plurality of post interconnects 223 of the metallization portion 202.

The method detaches (at 1330) the carrier. Stage 6 of FIG. 12C, illustrates and describes an example of a state after the carrier 1200 is detached from the encapsulation layer 106, the integrated device 205 and the integrated device 505. Stage 9 may illustrates a package 600 of FIG. 6.

### Exemplary Sequence for Fabricating a Metallization Portion

In some implementations, fabricating a substrate includes several processes. FIGS. 14A-14B illustrate an exemplary sequence for providing or fabricating a metallization portion. In some implementations, the sequence of FIGS. 14A-14B may be used to provide or fabricate the metallization portion 102. However, the process of FIGS. 14A-14B may be used to fabricate any of the metallization portions described in the disclosure.

It should be noted that the sequence of FIGS. 14A-14B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 14A, illustrates a state after a carrier 1400 is provided. A seed layer 1401 may be located over the carrier 1400. The carrier 1400 may be replaced with other components and/or materials.

Stage 2 illustrates a state after a plurality of interconnects 1412 are formed. The interconnects 1412 may be located over the seed layer 1401. A lithography process, a plating process, a strip process and/or an etching process may be used to form the plurality of interconnects 1412. The interconnects 1412 may represent at least some of the interconnects from the plurality of metallization interconnects 122.

Stage 3 illustrates a state after a dielectric layer 1410 is formed over the carrier 1400, the seed layer 1401 and the plurality of interconnects 1412. A deposition and/or lamination process may be used to form the dielectric layer 1410. The dielectric layer 1410 may include prepreg and/or polyimide. The dielectric layer 1410 may include a photo-imageable dielectric. However, different implementations may use different materials for the dielectric layer.

Stage 4 illustrates a state after a plurality of cavities 1413 is formed in the dielectric layer 1410. The plurality of cavities 1413 may be formed using an etching process (e.g., photo etching process), a laser process, an exposure process and/or a development process.

Stage 5 illustrates a state after interconnects 1422 are formed in and over the dielectric layer 1410, including in and over the plurality of cavities 1413. For example, a via, pad and/or traces may be formed. A lithography process, a plating process, a strip process and/or an etching process may be used to form the interconnects.

Stage 6, as shown in FIG. 14B, illustrates a state after a dielectric layer 1420 is formed over the dielectric layer 1410 and the plurality of interconnects 1422. A deposition and/or lamination process may be used to form the dielectric layer 1420. The dielectric layer 1420 may include prepreg and/or polyimide. The dielectric layer 1420 may include a photo-imageable dielectric. However, different implementations may use different materials for the dielectric layer.

Stage 7, illustrates a state after a plurality of cavities 1423 is formed in the dielectric layer 1440. The dielectric layer 1440 may represent the dielectric layer 1410 and/or the dielectric layer 1420. The plurality of cavities 1423 may be formed using an etching process (e.g., photo etching process), a laser process, an exposure process and/or a development process.

Stage 8 illustrates a state after interconnects 1432 are formed in and over the dielectric layer 1440, including in and over the plurality of cavities 1423. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

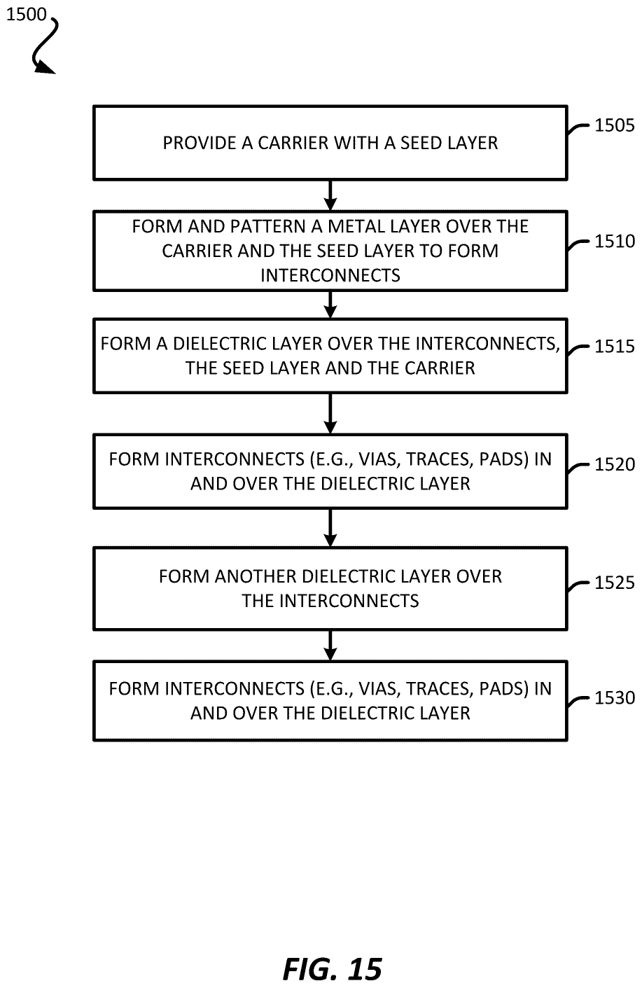

In some implementations, fabricating a substrate includes several processes. FIG. 15 illustrates an exemplary flow diagram of a method 1500 for providing or fabricating a metallization portion. In some implementations, the method 1500 of FIG. 15 may be used to provide or fabricate the metallization portion(s) of the disclosure. For example, the method 1500 of FIG. 15 may be used to fabricate the metallization portion 102.

It should be noted that the method 1500 of FIG. 15 may combine one or more processes in order to simplify and/or clarify the method for providing or fabricating a metallization portion. In some implementations, the order of the processes may be changed or modified.

The method provides (at 1505) a carrier with a seed layer. Stage 1 of FIG. 14A, illustrates and describes an example of a state after a carrier 1400 is provided. A seed layer 1401 may be located over the carrier 1400. The carrier 1400 may be replaced with other components and/or materials.

The method forms and patterns (at 1510) a plurality of interconnects. Stage 2 of FIG. 14A, illustrates and describes an example of a state after a plurality of interconnects 1412 are formed. The interconnects 1412 may be located over the seed layer 1401. A lithography process, a plating process, a strip process and/or an etching process may be used to form the plurality of interconnects 1412. The interconnects 1412 may represent at least some of the interconnects from the plurality of metallization interconnects 122.

The method forms (at 1510) a dielectric layer. Stage 3 of FIG. 14A, illustrates and describes an example of a state after a dielectric layer 1410 is formed over the carrier 1400, the seed layer 1401 and the plurality of interconnects 1412. A deposition and/or lamination process may be used to form the dielectric layer 1410. The dielectric layer 1410 may include prepreg and/or polyimide. The dielectric layer 1410 may include a photo-imageable dielectric. However, different implementations may use different materials for the dielectric layer.

The method forms (at 1520) a plurality of interconnects. Forming a plurality of interconnects may including forming a plurality of cavities in a dielectric layer and a performing a plating process. Stage 4 of FIG. 14A, illustrates and describes an example of a state after a plurality of cavities 1413 is formed in the dielectric layer 1410. The plurality of cavities 1413 may be formed using an etching process (e.g., photo etching process), a laser process, an exposure process and/or a development process.

Stage 5 of FIG. 14A, illustrates and describes an example of a state after interconnects 1422 are formed in and over the dielectric layer 1410, including in and over the plurality of cavities 1413. For example, a via, pad and/or traces may be formed. A lithography process, a plating process, a strip process and/or an etching process may be used to form the interconnects.

The method forms (at 1525) another dielectric layer. Stage 6 of FIG. 14B, illustrates and describes an example of a state after a dielectric layer 1420 is formed over the dielectric layer 1410 and the plurality of interconnects 1422. A deposition and/or lamination process may be used to form the dielectric layer 1420. The dielectric layer 1420 may include prepreg and/or polyimide. The dielectric layer 1420 may include a photo-imageable dielectric. However, different implementations may use different materials for the dielectric layer.

The method forms (at 1530) a plurality of interconnects. Forming a plurality of interconnects may including forming a plurality of cavities in a dielectric layer and a performing a plating process. Stage 7 of FIG. 14B, illustrates and describes an example of a state after a plurality of cavities 1423 is formed in the dielectric layer 1440. The dielectric layer 1440 may represent the dielectric layer 1410 and/or the dielectric layer 1420. The plurality of cavities 1423 may be formed using an etching process (e.g., photo etching process), a laser process, an exposure process and/or a development process.

Stage 8 of FIG. 14B, illustrates and describes an example of a state after interconnects 1432 are formed in and over the dielectric layer 1440, including in and over the plurality of cavities 1423. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

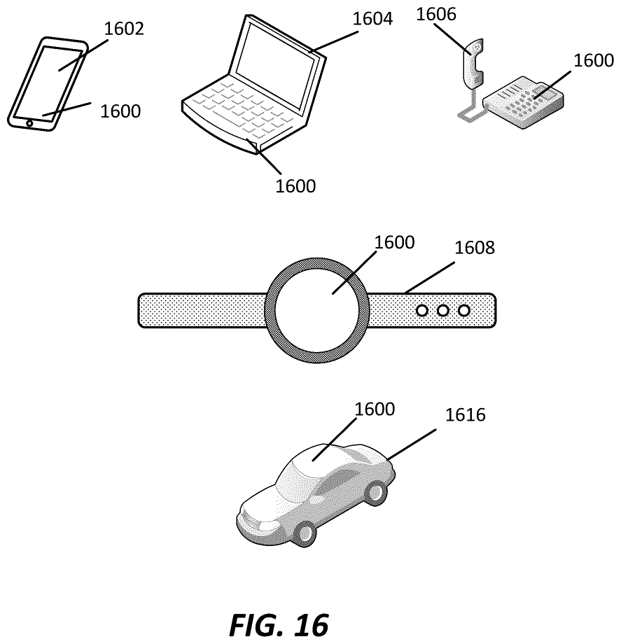

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-10, 11A-11C, 12A-12C, 13, 14A-14B, and 15-16 may be rearranged and/or combined into a single component, process, feature or function or embodied in several components, processes, or functions. Additional elements, components, processes, and/or functions may also be added without departing from the disclosure. It should also be noted FIGS. 1-10, 11A-11C, 12A-12C, 13, 14A-14B, and 15-16 and its corresponding description in the present disclosure is not limited to dies and/or ICs. In some implementations, FIGS. 1-10, 11A-11C, 12A-12C, 13, 14A-14B, and 15-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a metallization portion; an integrated device comprising a plurality of pillar interconnects, wherein the integrated device is coupled to the metallization portion through the plurality of pillar interconnects; and an encapsulation layer at least partially encapsulating the integrated device, wherein the encapsulation layer is coupled to the metallization portion.

Aspect 2: The package of aspect 1, wherein the metallization portion comprises at least one dielectric layer; and a plurality of metallization interconnects.

Aspect 3: The package of aspect 2, wherein the plurality of pillar interconnects are coupled to and touch the plurality of metallization interconnects.

Aspect 4: The package of aspects 2 through 3, wherein the metallization portion further comprises a plurality of post interconnects coupled to the plurality of metallization interconnects, and wherein the plurality of post interconnects comprises copper post interconnects.

Aspect 5: The package of aspects 1 through 4, further comprising a second integrated device comprising a second plurality of pillar interconnects, wherein the second integrated device is coupled to the metallization portion through the second plurality of pillar interconnects.

Aspect 6: The package of aspect 5, wherein the plurality of pillar interconnects includes a first pillar interconnect with a first height, and wherein the second plurality of pillar interconnects includes a second pillar interconnect with a second height that is different from the first height.

Aspect 7: The package of aspects 5 through 6, wherein the second plurality of pillar interconnects are coupled to and touch a plurality of metallization interconnects of the metallization portion.

Aspect 8: The package of aspects 1 through 4, further comprising a second integrated device coupled to the metallization portion through a plurality of solder interconnects.

Aspect 9: The package of aspect 8, wherein the plurality of solder interconnects are coupled to and touch a plurality of metallization interconnects of the metallization portion.

Aspect 10: The package of aspects 1 through 9, further comprising a second integrated device located at least partially in the encapsulation layer.

Aspect 11: The package of aspect 10, wherein the integrated device is a first system on chip (SoC), and wherein the second integrated device is a second system on chip (Soc).

Aspect 12: The package of aspect 10, wherein the integrated device is a system on chip (SoC), and wherein the second integrated device is a memory device.

Aspect 13: The package of aspects 1 through 12, further comprising a dummy silicon structure located at least partially in the encapsulation layer.

Aspect 14: The package of aspect 13, wherein the dummy silicon structure is coupled to a back side of the integrated device through an adhesive.

Aspect 15: A package comprising a metallization portion; an integrated device coupled to the metallization portion through a plurality of solder interconnects; and an encapsulation layer at least partially encapsulating the integrated device, wherein the encapsulation layer is coupled to the metallization portion.

Aspect 16: The package of aspect 15, wherein the metallization portion comprises at least one dielectric layer; and a plurality of metallization interconnects.

Aspect 17: The package of aspect 16, wherein the plurality of solder interconnects are coupled to and touch the plurality of metallization interconnects.

Aspect 18: The package of aspect 17, wherein the integrated device comprises a plurality of pad interconnects, and wherein the plurality of solder interconnects are coupled to and touch the plurality of pad interconnects.

Aspect 19: The package of aspects 17 through 18, further comprising a second integrated device comprising a plurality of pillar interconnects, wherein the second integrated device is coupled to the plurality of metallization interconnects of the metallization portion through the plurality of pillar interconnects.

Aspect 20: The package of aspects 15 through 19, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a metallization portion;
an integrated device comprising a plurality of pillar interconnects, wherein the integrated device is coupled to the metallization portion through the plurality of pillar interconnects; and
an encapsulation layer at least partially encapsulating the integrated device, wherein the encapsulation layer is coupled to the metallization portion.

2. The package of claim 1, wherein the metallization portion comprises:
at least one dielectric layer; and
a plurality of metallization interconnects.

3. The package of claim 2, wherein the plurality of pillar interconnects are coupled to and touch the plurality of metallization interconnects.

4. The package of claim 2,
wherein the metallization portion further comprises a plurality of post interconnects coupled to the plurality of metallization interconnects, and
wherein the plurality of post interconnects comprises copper post interconnects.

5. The package of claim 1, further comprising a second integrated device comprising a second plurality of pillar interconnects, wherein the second integrated device is coupled to the metallization portion through the second plurality of pillar interconnects.

6. The package of claim 5,
wherein the plurality of pillar interconnects includes a first pillar interconnect with a first height, and
wherein the second plurality of pillar interconnects includes a second pillar interconnect with a second height that is different from the first height.

7. The package of claim 5, wherein the second plurality of pillar interconnects are coupled to and touch a plurality of metallization interconnects of the metallization portion.

8. The package of claim 1, further comprising a second integrated device coupled to the metallization portion through a plurality of solder interconnects.

9. The package of claim 8, wherein the plurality of solder interconnects are coupled to and touch a plurality of metallization interconnects of the metallization portion.

10. The package of claim 1, further comprising a second integrated device located at least partially in the encapsulation layer.

11. The package of claim 10,
wherein the integrated device is a first system on chip (SoC), and
wherein the second integrated device is a second system on chip (Soc).

12. The package of claim 10,
wherein the integrated device is a system on chip (SoC), and
wherein the second integrated device is a memory device.

13. The package of claim 1, further comprising a dummy silicon structure located at least partially in the encapsulation layer.

14. The package of claim 13, wherein the dummy silicon structure is coupled to a back side of the integrated device through an adhesive.

15. A package comprising:
a metallization portion;
an integrated device coupled to the metallization portion through a plurality of solder interconnects; and
an encapsulation layer at least partially encapsulating the integrated device,
wherein the encapsulation layer is coupled to the metallization portion.

16. The package of claim 15, wherein the metallization portion comprises:
at least one dielectric layer; and
a plurality of metallization interconnects.

17. The package of claim 16, wherein the plurality of solder interconnects are coupled to and touch the plurality of metallization interconnects.

18. The package of claim 17,
wherein the integrated device comprises a plurality of pad interconnects, and
wherein the plurality of solder interconnects are coupled to and touch the plurality of pad interconnects.

19. The package of claim 17, further comprising a second integrated device comprising a plurality of pillar interconnects, wherein the second integrated device is coupled to the plurality of metallization interconnects of the metallization portion through the plurality of pillar interconnects.

20. The package of claim 15, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
